(19) United States
(12) Patent Application Publication
(10) Pub. No.: US 2026/0214802 A1
(43) Pub. Date: Jul. 23, 2026

(54) ELECTRONIC EQUIPMENT

(71) Applicant: CANON KABUSHIKI KAISHA, Tokyo (JP)

(72) Inventor: YOSHITAKA KAWASE, Kanagawa (JP)

(21) Appl. No.: 19/448,871

(22) Filed: Jan. 14, 2026

(30) Foreign Application Priority Data
Jan. 17, 2025 (JP) 2025-006919

(51) Int. Cl. H05K 1/14; H04N 23/68; H04N 25/709

(52) U.S. Cl. CPC H05K 1/147; H04N 25/709; H04N 23/687

(57) ABSTRACT

Equipment includes a first module that supplies first and second powers, a flexible wiring unit, and a second module to which the first and second powers are supplied via the flexible wiring unit. The flexible wiring unit includes first and second power wirings for transmitting the first power, and third and fourth power wirings for transmitting the second power. The first power wiring is arranged alongside with the second power wiring in a first direction and is arranged alongside with the fourth power wiring in a second direction orthogonal to the first direction. The third power wiring is arranged alongside with the fourth power wiring in the first direction, and is arranged alongside with the second power wiring in the second direction.

### BACKGROUND

### Field of the Technology

The present disclosure relates to electronic equipment.

### Description of the Related Art

In recent years, as electronic equipment has become more advanced, the power consumption of semiconductor components has increased, and unwanted magnetic noise from current in the power supply system has started to affect the performance of peripheral components. For example, in an imaging device such as a digital camera, a high-definition image sensor needs to continuously process a large amount of data over an extended period. Therefore, the power consumption of the image sensor increases significantly.

The electronic equipment discussed in Japanese Patent Laid-Open No. 2023-100676 uses a flexible wiring board to supply power. However, magnetic field noise emitted from the flexible wiring board may degrade the quality of the captured image.

### SUMMARY

An aspect of the present disclosure provides electronic equipment that includes a first module configured to supply a first power and a second power; a flexible wiring unit that includes a first power wiring and a second power wiring for transmitting the first power, and a third power wiring and a fourth power wiring for transmitting the second power; and a second module configured to receive the first power and the second power are supplied via the flexible wiring unit. While the first power and the second power are being transmitted, each of a first potential difference between the first power wiring and the fourth power wiring, and a second potential difference between the second power wiring and the third power wiring, is greater than a potential difference between the second power wiring and the fourth power wiring. The first power wiring is arranged alongside with the second power wiring in a first direction and is arranged alongside with the fourth power wiring in a second direction orthogonal to the first direction. The third power wiring is arranged alongside with the fourth power wiring in the first direction and is arranged alongside with the second power wiring in the second direction.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic view of a configuration of electronic equipment according to a first embodiment.

FIG. 2A is a side view of a configuration of a power receiving module, a flexible wiring unit, and a power supply module according to the first embodiment.

FIG. 2B is a block diagram of a configuration of a digital camera according to the first embodiment.

FIG. 3 is a plan view of a configuration of the power receiving module and the flexible wiring unit according to the first embodiment.

FIG. 4 is a cross-sectional view taken along line A-A′ of FIG. 3.

FIG. 5 is a side view of a configuration of a power receiving module, a flexible wiring unit, and a power supply module according to a second embodiment.

FIG. 6A is a plan view of a configuration of the power receiving module and the flexible wiring unit according to the second embodiment.

FIG. 6B is a plan view illustrating an example of a connection structure of a first flexible wiring board and a second flexible wiring board according to the second embodiment.

FIG. 6C is a plan view of a configuration of the power receiving module according to the second embodiment.

FIG. 7A is a cross-sectional view taken along line A-A′ of FIG. 6A.

FIG. 7B is a cross-sectional view taken along line B-B′ of FIG. 6A.

FIG. 8 is a plan view of a configuration of a power receiving module and a flexible wiring unit according to a third embodiment.

FIG. 9 is a cross-sectional view taken along line A-A′ of FIG. 8.

FIG. 10 is a plan view of a configuration of a power receiving module and a flexible wiring unit according to a fourth embodiment.

FIG. 11 is a cross-sectional view taken along line A-A′ of FIG. 10.

FIG. 12 is a plan view of a configuration of a power receiving module and a flexible wiring unit according to a fifth embodiment.

FIG. 13 is a cross-sectional view taken along line A-A′ of FIG. 12.

FIG. 14 is a graph of the phase difference of the current flowing through a power wiring.

FIG. 15A is a side view of a configuration of a power supply module, a power receiving module, and a flexible wiring unit according to a sixth embodiment.

FIG. 15B is a plan view of a configuration of the power supply module, the power receiving module, and the flexible wiring unit according to the sixth embodiment.

FIG. 16 is a graph illustrating simulation results of magnetic flux density in Examples and Comparative Examples.

### DESCRIPTION OF THE EMBODIMENTS

Hereinafter, embodiments for implementing the present disclosure will be described in detail with reference to the drawings. The present disclosure is not limited to the following embodiments and may be modified appropriately without departing from the gist thereof. In the drawings described below, components having the same function are denoted by the same reference numerals. For conciseness, the description thereof may be incorporated by reference.

### First Embodiment

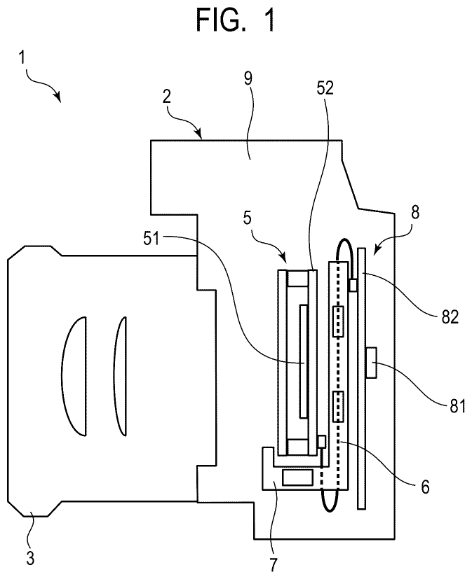

Electronic equipment, according to a first embodiment, will be described with reference to FIGS. 1 to 4. FIG. 1 is a schematic diagram of a configuration of the electronic equipment according to the first embodiment. Here, a digital camera 1 is illustrated as an example of the electronic equipment. The digital camera 1 includes a camera body 2 and a lens unit 3 (lens barrel). The camera body 2 includes a casing 9 for storing a power receiving module 5 (second module), a flexible wiring unit 6, a camera shake correction mechanism 7, and a power supply module 8 (first module). The lens unit 3 is interchangeable with the camera body 2 or is integrated with the camera body 2 for guiding light from an object to the semiconductor element 51.

Power is supplied to the power receiving module 5 from the power supply module 8 via the flexible wiring unit 6. The flexible wiring unit 6 includes one or more flexible wiring elements. Each flexible wiring element is, for example, either a flexible printed circuit board (FPC) or a flexible flat cable (FFC). The flexible wiring unit 6 may comprise a single flexible wiring element or an assembly of multiple flexible wiring elements. In this example, the power receiving module 5 includes a single wiring board 52, but the power receiving module 5 may include a plurality of wiring boards, and the flexible wiring unit 6 may be connected to the plurality of wiring boards of the power receiving module 5. In this example, the power supply module 8 includes a single wiring board 82. However, the power supply module 8 may include a plurality of wiring boards, and the flexible wiring unit 6 may be connected to the plurality of wiring boards of the power supply module 8. The wiring board 52 may be referred to as a power receiving board, and the wiring board 82 may be referred to as a power supply board.

The power receiving module 5 includes a semiconductor element 51 and a wiring board 52. The semiconductor element 51 is an imaging device having a light receiving unit 50 for receiving light from an object. Therefore, the power receiving module 5 may be referred to as an imaging module. The wiring board 52 supplies current to the semiconductor element 51 mounted on the main surface. The power supply module 8 has a semiconductor component 81 and a wiring board 82. The semiconductor component 81 is an electronic component for image processing that processes an image acquired by imaging at high speed. Therefore, the power supply module 8 may be referred to as an image processing module. The wiring board 82 is provided with a wiring pattern for inputting and outputting signals to and from the semiconductor component 81. The wiring board 52 may be referred to as an imaging board, and the wiring board 82 may be referred to as an image processing board. The flexible wiring unit 6 has a plurality of wirings for electrically connecting the wiring board 52 and the wiring board 82.

The camera shake correction mechanism 7 is configured to correct image blur in captured images. The camera shake correction mechanism 7 moves the power receiving module 5 relative to the power supply module 8 within the casing 9. The camera shake correction mechanism 7 includes an actuator that controls the position of the semiconductor element 51. When the power receiving module 5 moves relative to the power supply module 8, the flexible wiring unit 6 deforms to follow the displacement between the power receiving module 5 and the power supply module 8.

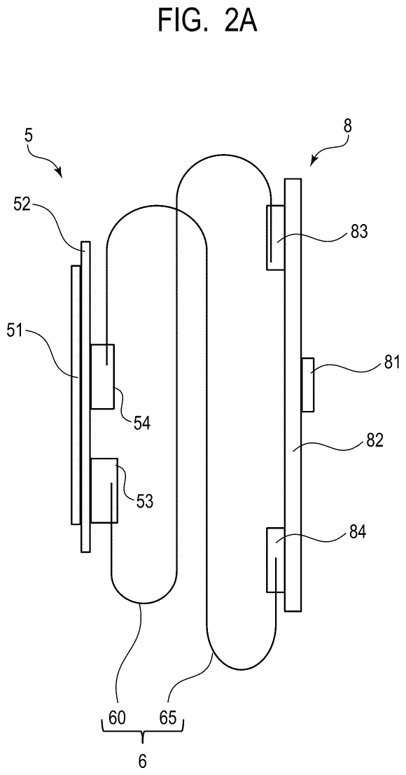

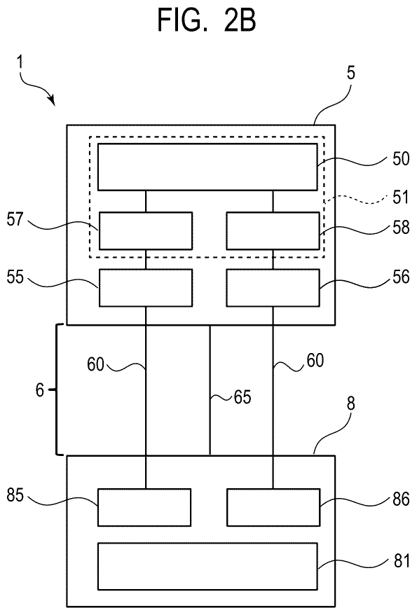

FIG. 2A is a side view of a configuration of the power receiving module 5, the flexible wiring unit 6, and the power supply module 8 according to the first embodiment. FIG. 2A illustrates the arrangement of the semiconductor element 51, the wiring board 52, the flexible wiring unit 6, and the power supply module 8 included in the power receiving module 5. In the first embodiment, the flexible wiring unit 6 is composed of two pieces of the flexible wiring board 60 for power supply and the flexible wiring board 65 for signal transmission. The wiring board 52 has a connector 53 and a connector 54 on a surface opposite to the surface on which the semiconductor element 51 is provided. The wiring board 82 has a connector 83 and a connector 84 on a surface opposite to the surface on which the semiconductor component 81 is provided. One end of the flexible wiring board 60 for power supply is connected to the connector 53 of the wiring board 52, and the other end is connected to the connector 83 of the power supply module 8. One end of the flexible wiring board 65 for signal transmission is connected to the connector 54 of the power receiving module 5, and the other end is connected to the connector 84 of the power supply module 8. The method of connecting the flexible wiring unit 6 to the power receiving module 5 and the power supply module 8 is not limited to this method. At least some terminals of the flexible wiring unit 6 may be soldered to the circuit boards (wiring board 52 and wiring board 82) of the respective modules. For example, one end of the flexible wiring board 65 for signal transmission may be soldered to the power receiving module 5, and the other end of the flexible wiring board 65 for signal transmission may be soldered to the connector 84 of the power supply module 8. One end of the flexible wiring board 65 for signal transmission may be soldered to the power receiving module 5, and one end of the flexible wiring board 60 for power supply may be connected to the connector of the power receiving module 5.

FIG. 2B is a block diagram of a configuration of the digital camera 1 according to the first embodiment. The power receiving module 5 may include a first relay circuit 55 and a second relay circuit 56 in addition to the light receiving unit 50. The power receiving module 5 may include an analog circuit 57 and a digital circuit 58 as circuit units. Examples of the analog circuit 57 include a pixel circuit, a readout circuit, a clock generating circuit, a bias generating circuit, and the like. Examples of the digital circuit 58 include an A/D conversion circuit, a digital control circuit, an image signal processor (ISP), a data buffering circuit, a communication circuit, and the like. The first relay circuit 55 supplies power to the analog circuit 57. The second relay circuit 56 supplies power to the digital circuit 58. The first relay circuit 55 and the second relay circuit 56 may include wiring of the wiring board 52. The first relay circuit 55 and the second relay circuit 56 may include connecting members, such as bonding wires, for connecting the semiconductor element 51 to the wiring board 52. The first relay circuit 55 and the second relay circuit 56 may include connecting members such as connectors for connecting the wiring board 52 and the flexible wiring unit 6. The first relay circuit 55 and the second relay circuit 56 may include capacitors and inductors for preventing noise. The first relay circuit 55 and the second relay circuit 56 may include voltage conversion circuits, such as level shift circuits, for boosting or dropping voltage.

In the example of FIG. 2B, the semiconductor element 51 having the light receiving unit 50 is illustrated, which includes an analog circuit 57 and a digital circuit 58. At least a part of at least one of the analog circuits 57 and the digital circuit 58 may be provided in a semiconductor device other than the semiconductor element 51 having the light receiving unit 50, and this other semiconductor device may be laminated on the semiconductor element 51. In the example of FIG. 2B, the first relay circuit 55 and the second relay circuit 56 are provided as semiconductor elements separate from the semiconductor element 51 that has the light receiving unit 50. However, in at least one of the first relay circuit 55 and the second relay circuit 56, at least a part thereof may be provided in the semiconductor element 51 having the light receiving unit 50 or may be provided in a semiconductor device laminated on the semiconductor element 51 having the light receiving unit 50.

The power supply module 8 includes a first power source 85 and a second power source 86 in addition to the semiconductor component 81. The first power source 85 and the second power source 86 are, for example, DC-DC converters. The first power source 85 and the second power source 86 may be composed of a single semiconductor element or a plurality of semiconductor elements. In FIG. 2B, the first relay circuit 55 is connected to the first power source 85 via the flexible wiring board 60 for power supply. The second relay circuit 56 is connected to the second power source 86 via a flexible wiring board 60 for power supply. Since power may be supplied from the first power source 85 to the analog circuit 57 via the flexible wiring unit 6, the configuration of the first relay circuit 55 may be appropriately designed. Since power may be supplied from the second power source 86 to the digital circuit 58 via the flexible wiring unit 6, the configuration of the second relay circuit 56 may be appropriately designed.

The flexible wiring unit 6 has four or more power wirings for power transmission from the power supply module 8 to the power receiving module 5. The power of one system corresponds to the product of the voltage of the two power wirings and the current flowing therethrough. Among the pair of power wirings to which the voltage (potential difference) of this power is applied, the power wiring of the high potential is the high-potential wiring, and the power wiring of the low potential is the low-potential wiring. The four or more power wirings of the flexible wiring unit 6 are two power wirings of a pair (first pair) and two power wirings of another pair (second pair). The power transmitted by the two power wirings of the first pair is referred to as a first power, and the power transmitted by the two power wirings of the second pair is referred to as a second power. The magnitudes of the first power and the second power may be equal or different, with the present embodiment directed to different magnitudes of the first power and the second power. Typically, the power corresponding to the first power is supplied to the analog circuit 57, and the power corresponding to the second power is supplied to the digital circuit 58. The magnitude of the first power transmitted by the flexible wiring unit 6 and the magnitude of the power supplied to the analog circuit 57 need not be completely identical and may be changed by the first relay circuit 55. The magnitude of the second power transmitted by the flexible wiring unit 6 and the magnitude of the power supplied to the digital circuit 58 need not be completely identical and may be changed by the second relay circuit 56.

Among a first pair of two power wirings transmitting the first power, one power wiring is a first power wiring, and the other power wiring is a second power wiring. Among a second pair of two power wirings for transmitting the second power, one power wiring is a third power wiring, and the other power wiring is a fourth power wiring. While the first power and the second power are being transmitted, each of a potential difference between the first power wiring and the fourth power wiring and between the second power wiring and the third power wiring is greater than a potential difference between the second power wiring and the fourth power wiring. While the first power and the second power are being transmitted, the relationship between the potential V1 applied to the first power wiring, the potential V2 applied to the second power wiring, the potential V3 applied to the third power wiring, and the potential V4 applied to the fourth power wiring, may be |V1-V4|>|V2-V4| and |V2-V3|>|V2-V4|. The potential difference between the second power wiring and the fourth power wiring may or may not be zero (|V2-V4|>0). V1 may be greater than V4, V1 may be less than V4, V2 may be greater than V3, V2 may be less than V3, or V2 may be less than or equal to V3. In the following embodiments, a case where V1>V2 is satisfied, that is, a case where the first power wiring is a high-potential wiring and the second power wiring is a low-potential wiring, will be described. Additionally, a case where V3>V4 is satisfied, that is, the third power wiring is a high-potential wiring, and the fourth power wiring is a low-potential wiring, will be described. Even if either V1<V2 or V3<V4 is satisfied, it is sufficient to satisfy |V1-V4|>|V2-V4| and |V2-V3|>|V2-V4|. In the following embodiments, both V1 and V3 are described as positive power supply potentials, and both V2 and V4 are described as ground potentials. However, V1 and V3 may be positive power supply potentials, and V2 and V4 may be negative power supply potentials. The value of the power supply potential may be, for example, greater than or equal to 0.5 [V], less than or equal to 13 [V], greater than or equal to 1.0 [V], less than or equal to 6.0 [V], or less than or equal to 4.0 [V]. The potential V1 and the potential V3, which are exemplified as the positive power supply potential, may be the same or different. For example, the potential V1 corresponding to the power supplied to the analog circuit 57 may be higher than the potential V3 corresponding to the power supplied to the digital circuit 58. The potential V2 and the potential V4, which are exemplified as the ground potential, may be the same or different. That is, at least one of the potential V2 and the potential V4 may not coincide with the frame ground potential of the electronic equipment. For example, the potential V2 corresponding to the power supplied to the analog circuit 57 may be lower than the potential V4 corresponding to the power supplied to the digital circuit 58. The power supply potentials may be substantially the same, and the ground potentials may be substantially the same.

In the present embodiment, the first power wiring is arranged side by side with the second power wiring in a first direction and is arranged side by side with the fourth power wiring in a second direction that is orthogonal to the first direction. The third power wiring is arranged side by side with the fourth power wiring in the first direction and is arranged side by side with the second power wiring in the second direction. Arranging the power wirings in this manner reduces magnetic field noise.

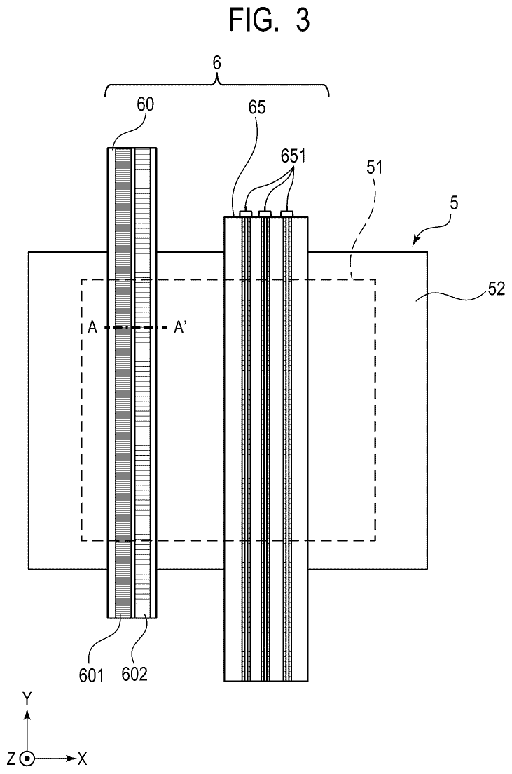

FIG. 3 is a plan view of a configuration of the power receiving module 5 and the flexible wiring unit 6 according to the first embodiment. FIG. 3 illustrates an XYZ orthogonal coordinate system. The X-direction, the Y-direction, and the Z-direction are orthogonal to each other. That is, the X-direction and the Y-direction are orthogonal, and the Z-direction is orthogonal to the X-direction and the Y-direction. FIG. 3 is a plan view of the wiring board 52 when viewed from the side of the wiring board 82. FIG. 3 illustrates arrangements of the flexible wiring board 60 for power supply, the flexible wiring board 65 for transmitting signals, the semiconductor element 51, and the wiring board 52. The flexible wiring board 60 for power supply is a flexible wiring board including a first conductor layer and a second conductor layer laminated to each other in the Z-direction. The power wiring 601 and the power wiring 602 are arranged in the first conductor layer. The power wiring 601 corresponds to the first power wiring to which the above-described power supply potential (potential V1) is applied. The power wiring 602 corresponds to the second power wiring to which the above-described ground potential (potential V2) is applied. The power wiring 601 is arranged side by side with the power wiring 602 in the X-direction in a plan view of the flexible wiring unit 6. The power wiring 601 and the power wiring 602 transmit the first power. The power wiring 601 and the power wiring 602 extend in the Y-direction in a plan view, and a current flows in the power wiring 601 and the power wiring 602 along the Y-direction. The second conductor layer constituting the lower layer of the first conductor layer will be described later. The flexible wiring unit 6 overlaps the semiconductor element 51 in the Z-direction.

The flexible wiring board 65 for signal transmission includes a plurality of differential signal lines 651. The differential signal lines 651 transmit electric signals using two signal lines. When a signal flows on one signal line, a signal of opposite phase flows on the other signal line. Thus, the influence of external noise is minimized, and high-speed and high-quality signal transmission is realized. Although three differential signal lines 651 are illustrated in FIG. 3, the number of differential signal lines 651 provided on the flexible wiring board 65 for signal transmission may be greater than or equal to four, greater than or equal to eight, or greater than or equal to sixteen. In the present embodiment, when light incident on the semiconductor element 51 is converted into an electric signal, the electric signal is transmitted to the power supply module 8 at high speed by the differential signal line 651 of the flexible wiring board 65.

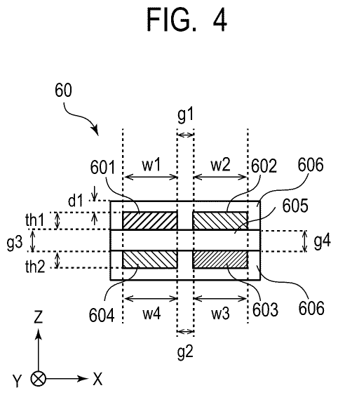

FIG. 4 is a cross-sectional view taken along line A-A′ of the flexible wiring board 60 illustrated in FIG. 3. As illustrated in FIG. 4, the flexible wiring board 60 includes a base material 605, a first conductor layer disposed on one surface (upper surface) of the base material 605, a second conductor layer disposed on the other surface (lower surface) of the base material 605, and a coverlay 606. The power wiring 601 and the power wiring 602 are disposed in the first conductor layer. The power wiring 601 corresponds to the first power wiring to which the above-described power supply potential (potential V1) is applied. The power wiring 602 corresponds to the second power wiring to which the above-described ground potential (potential V2) is applied. A power wiring 603 and a power wiring 604 are disposed in the second conductor layer. The power wiring 603 corresponds to a third power wiring to which the above-described power supply potential (potential V3) is applied. The power wiring 604 corresponds to a fourth power wiring to which the above-described ground potential (potential V4) is applied. The base material 605 is formed of polyimide. The first conductor layer and the second conductor layer are formed of copper foil. A thickness th1 of the first conductor layer in the Z-direction and a thickness th2 of the second conductor layer in the Z-direction may be, for example, greater than or equal to 1 μm, less than 100 μm, greater than or equal to 5 μm, or less than or equal to 50 μm. The thickness of the power wiring 601 in the Z-direction and the thickness of the power wiring 602 in the Z-direction are substantially the same and are expressed as the thickness th1. The thickness of the power wiring 603 in the Z-direction and the thickness of the power wiring 604 in the Z-direction are substantially the same and are expressed as the thickness th2. The coverlay 606 is an insulating member covering the power wiring 601, the power wiring 602, the power wiring 603, and the power wiring 604. The power wiring 603 and the power wiring 604 are arranged in the second conductor layer. The power wiring 603 is arranged side by side with the power wiring 604 in the X-direction. A spacing g1 between the power wiring 601 and the power wiring 602, and a spacing g2 between the power wiring 603 and the power wiring 604 in the X-direction are, for example, greater than or equal to 10 μm, less than or equal to 500 μm, greater than or equal to 50 μm, and less than or equal to 100 μm. The power wiring 603 and 604 transmit the second power. The power wiring 603 and 604 extend in the Y-direction in a plan view, and currents flow in the power wiring 603 and 604 along the Y-direction. The values of currents flowing in the power wirings 601 and 603 are, for example, greater than or equal to 0.5 [A] and less than or equal to 3.0 [A].

The power wiring 603 is arranged to face the power wiring 602 in the Z-direction. Therefore, as illustrated in FIG. 3, the power wiring 603 overlaps the power wiring 602 in a plan view of the flexible wiring unit 6. Similarly, the power wiring 601 is arranged to be aligned with and face the power wiring 604 in the Z-direction. As illustrated in FIG. 3, the power wiring 601 overlaps the power wiring 604 in a plan view. In the first embodiment, the power wiring 601 is connected to the analog circuit 57, and the power wiring 603 is connected to the digital circuit 58. Conversely, the power wiring 603 may be connected to the analog circuit 57, and the power wiring 601 may be connected to the digital circuit 58. A spacing g3 between the power wirings 601 and 604 and a spacing g4 between the power wiring 603 and 602 in the Z-direction may be, for example, greater than or equal to 10 μm, less than or equal to 500 μm, greater than or equal to 50 μm, or less than or equal to 100 μm. The spacing g3 between the power wiring 601 and the power wiring 604 in the Z-direction may be larger than the thickness th1 of the power wiring 601 in the Z-direction and/or the thickness th2 of the power wiring 604 in the Z-direction. The spacing g4 between the power wiring 602 and the power wiring 603 in the Z-direction may be larger than the thickness th1 of the power wiring 602 in the Z-direction and/or the thickness th2 of the power wiring 603 in the Z-direction. A width w1 of the power wiring 601 in the X-direction may be larger than the thickness th1 of the power wiring 601 in the Z-direction, and a width w2 of the power wiring 602 in the X-direction may be larger than the thickness th1 of the power wiring 602 in the Z-direction. A width w3 of the power wiring 603 in the X-direction may be larger than the thickness th2 of the power wiring 603 in the Z-direction, and the width w4 of the power wiring 604 in the X-direction may be larger than the thickness th2 of the power wiring 604 in the Z-direction.

The spacing g1 between the power wiring (first power wiring) 601 and the power wiring (second power wiring) 602 in the X-direction (first direction) may be smaller than the width w1 of the power wiring 601 and the width w2 of the power wiring 602 in the X-direction. The spacing g2 between the power wiring (third power wiring) 603 and the power wiring (fourth power wiring) in the X-direction may be smaller than the width w3 of the power wiring 603 and the width w4 of the power wiring 604. The spacing g3 between the power wiring 601 and the power wiring 604 in the Z-direction (second direction) may be smaller than the width w1 of the power wiring 601 and the width w4 of the power wiring 604 in the X-direction. The spacing g4 between the power wiring 602 and the power wiring 603 in the Z-direction may be smaller than the width w2 of the power wiring 602 and the width w3 of the power wiring 603 in the X-direction. The width w1 of the power wiring 601, the width w2 of the power wiring 602, the width w3 of the power wiring 603, and the width w4 of the power wiring 604 in the X-direction may be, for example, greater than or equal to 100 μm, greater than or equal to 250 μm, greater than or equal to 500 μm, less than or equal to 5 mm, less than or equal to 2.5 mm, less than or equal to 1000 μm, or less than or equal to 750 μm.

The width w1 of the power wiring 601 may be substantially the same as the width w2 of the adjacent power wiring 602. The width w3 of the power wiring 603 may be substantially the same as the width w4 of the adjacent power wiring 604. The width w3 of the power wiring 603 may be substantially the same as the width w2 of the opposing power wiring 602. The width w4 of power wiring 604 may be substantially the same as the width w1 of the opposing power wiring 601. These widths w1 to w4 are, for example, 630 μm. The spacing g1 between power wiring 601 and power wiring 602 is, for example, 70 μm. With value A and value B being substantially the same, value A/value B is 100±10%. For example, if the value A and value B represent a width, w1/w2 and w3/w4 are 100±10%.

As described above, in the first conductor layer, power wiring 601 is arranged side by side with power wiring 602 through which current flows in a direction opposite to that of power wiring 601. Similarly, in the second conductor layer, the power wiring 603 is arranged side by side with the power wiring 604 through which current flows in a direction opposite to that of the power wiring 603. Thus, the effect of canceling the magnetic field is enhanced. The power wiring 601 of the first conductor layer is arranged side by side with the power wiring 604 of the second conductor layer in the vertical direction (Z-direction). The power wiring 603 of the second conductor layer, which is a lower layer of the first conductor layer, is arranged side by side with the power wiring 602 of the first conductor layer in the vertical direction (Z-direction). Thus, the effect of canceling the magnetic field is further enhanced by arranging the power wirings 601 and 603 side by side with the power wirings 602 and 604 in the lateral direction (X-direction) and arranging the power wirings 601 and 603 to face the power wirings 604 and 602 in the vertical direction (Z-direction). When the width of the power wirings and the width of the power wirings are substantially the same, the effect of canceling the magnetic field can be further enhanced. The larger the width of the power wirings in the X-direction, the greater the coupling with the power wirings arranged in the Z-direction. The smaller the distance between the power wirings and the power wirings arranged in the X or Z-direction, the greater the coupling with the power wirings arranged in the X or Z-direction. Therefore, the relation {w1, w2, w3, w4}>{g3, g4}>{g1, g2}>{th1, th2} or {w1, w2, w3, w4}>{g1, g2}>{g3, g4}>{th1, th2} is typically satisfied.

An example in which one power system is arranged in the same conductor layer has been described, but this is not limited thereto. For example, the power wirings 601 and 604 may be arranged in the first conductor layer, and the power wirings 602 and 603 may be arranged in the second conductor layer. In this case, the power wiring 601 is arranged alongside (preferably side by side or overlapped) with the power wiring 602 in the Z-direction and is arranged side by side with the power wiring 604 in the X-direction orthogonal to the Z-direction. The power wiring 603 is arranged alongside (preferably side by side or overlapped) with the power wiring 604 in the Z-direction and is arranged side by side with the power wiring 602 in the X-direction.

### Second Embodiment

Hereinafter, electronic equipment according to a second embodiment will be described. In the first embodiment, the flexible wiring board 60 for power supply is a double-sided flexible wiring board having a two-layer structure. In the second embodiment, the power supply flexible wiring board is composed of two single-sided flexible wiring boards. In the second embodiment, one of the two power supply flexible wiring boards is formed in a straight shape, and the other is formed in a bent shape. The second embodiment differs from the first embodiment in the number of flexible wiring boards constituting the flexible wiring unit 6 and the shape of the flexible wiring boards.

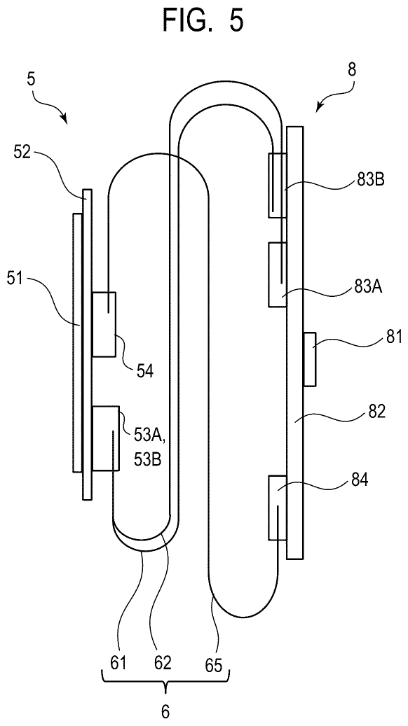

FIG. 5 is a side view of a configuration of a power receiving module 5, a flexible wiring unit 6, and a power supply module 8 according to the second embodiment. The flexible wiring unit 6 of the present embodiment has a first flexible wiring board 61 and a second flexible wiring board 62 as flexible wiring boards for power supply. Each of the first flexible wiring board 61 and the second flexible wiring board 62 has a plurality of power wirings. One end of the first flexible wiring board 61 is connected to a connector 53A provided on the wiring board 52. The other end of the first flexible wiring board 61 is connected to a connector 83A provided on the wiring board 82. One end of the second flexible wiring board 62 is connected to a connector 53B provided on the wiring board 52. The other end of the second flexible wiring board 62 is connected to a connector 83B provided on the wiring board 82. The configuration of the flexible wiring board 65 for signal transmission is the same as that of the first embodiment.

In the second embodiment, power is transmitted from the power supply module 8 to the power receiving module 5 using the first flexible wiring board 61 and the second flexible wiring board 62. Generally, a high specification digital camera requires a large current of approximately 0.5 to 3.0 [A] to flow. Therefore, a plurality of flexible wiring boards for power supply is provided to accommodate wiring migration. Although the first power in the second embodiment is different from the second power, the first power and the second power may be the same.

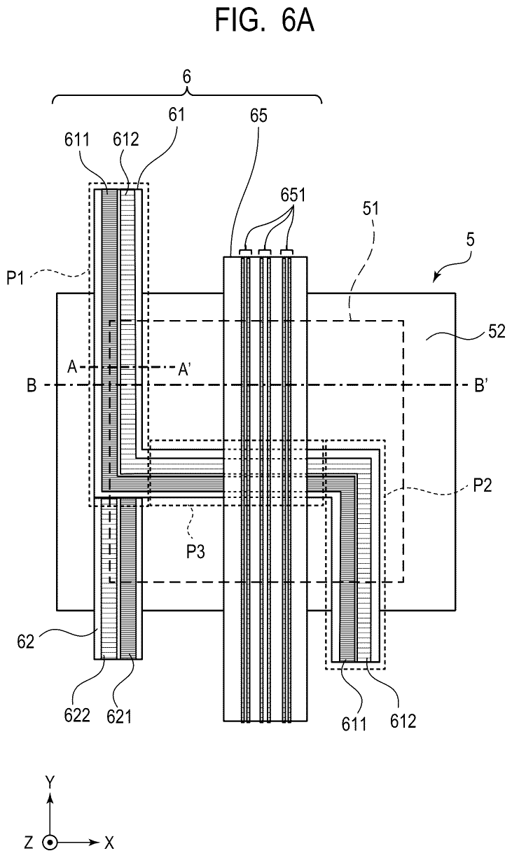

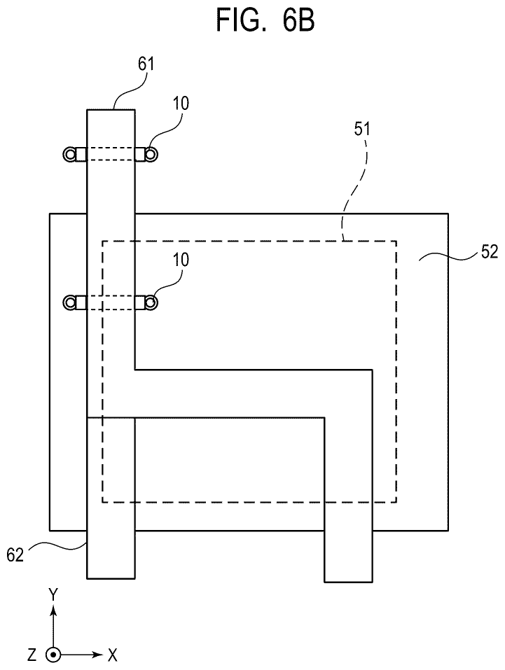

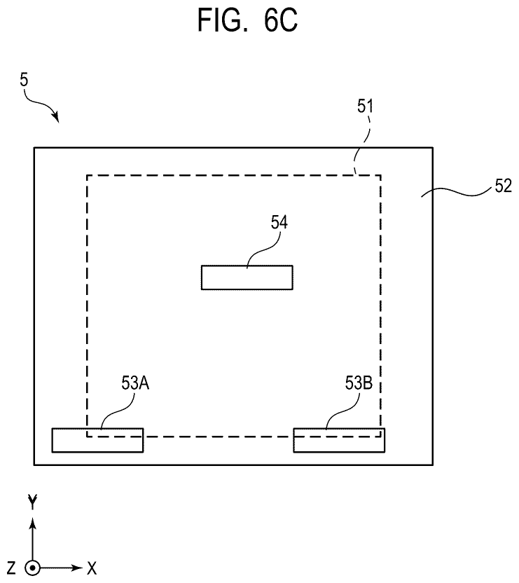

FIG. 6A is a plan view of a configuration of the power receiving module 5 and the flexible wiring unit 6 according to the second embodiment. FIG. 6A is a plan view of the wiring board 52 when viewed from the side of the wiring board 82. FIG. 6A illustrates arrangements of the first flexible wiring board 61, the second flexible wiring board 62, the flexible wiring board 65, the semiconductor element 51, and the wiring board 52. The first flexible wiring board 61 and the second flexible wiring board 62 are single-sided flexible wiring boards in which a conductor layer is provided on only one surface. In the first flexible wiring board 61, the power wiring 611 is arranged side by side with the power wiring 612 in the X-direction. The power wiring 611 and the power wiring 612 transmit the first power. The power wiring 611 corresponds to the first power wiring to which the above-described power supply potential (potential V1) is applied. The power wiring 612 corresponds to the second power wiring to which the above-described ground potential (potential V2) is applied. In the second flexible wiring board 62, the power wiring 621 is arranged side by side with the power wiring 622. The power wiring 621 and the power wiring 622 transmit the second power. The power wiring 621 corresponds to the third power wiring to which the above-described power supply potential (potential V3) is applied. The power wiring 622 corresponds to the fourth power wiring to which the above-described ground potential (potential V4) is applied.

At least a portion of the first flexible wiring board 61 for power supply is arranged to overlap the semiconductor element 51 in a plan view. Similarly, at least in part of the second flexible wiring board 62 is arranged to overlap the semiconductor element 51 in a plan view. The first flexible wiring board 61 and the second flexible wiring board 62 are arranged to overlap at least a part of them on a path until they are connected to the wiring board 82.

As illustrated in FIG. 6A, the second flexible wiring board 62 is linearly formed. On the other hand, the first flexible wiring board 61 includes a first substrate portion P1 that overlaps the second flexible wiring board 62 in a plan view and is connected to the power receiving module (second module) 5, a second substrate portion P2 that does not overlap the second flexible wiring board 62 and is connected to the power supply module (first module) 8, and a third substrate portion P3 that positions between the first substrate portion P1 and the second substrate portion P2. The flexible wiring board for signal transmission (third flexible wiring board) 65 is arranged to intersect the third substrate portion P3 in a plan view.

By providing two flexible wiring boards (first flexible wiring board 61 and second flexible wiring board 62) for power supply and separating power supplies, there is an effect of avoiding wiring migration. In addition, by arranging at least a part of the first flexible wiring board 61 to overlap the second flexible wiring board 62, the area and volume of arranging the flexible wiring boards are reduced, and miniaturization of electronic equipment is realized.

FIG. 6B is a plan view illustrating an example of a connection structure of the first flexible wiring board 61 and the second flexible wiring board 62 according to the second embodiment. Here, two fixing members 10 are provided below the first flexible wiring board 61 and the second flexible wiring board 62. The fixing member 10 includes openings at both ends for inserting screws. A metal plate or the like is provided within the casing 9 of the camera body 2, serving as the fixed portion for the first flexible wiring board 61 and the second flexible wiring board 62. The fixing member 10 positions the second flexible wiring board 62 with respect to the first flexible wiring board 61 and fixes the first flexible wiring board 61 and the second flexible wiring board 62 to the casing 9 of the camera body 2. The first flexible wiring board 61 and the second flexible wiring board 62 may be bonded to a metal plate or the like that constitutes the casing 9 of the camera body 2 with an adhesive.

FIG. 6C is a plan view of a configuration of the power receiving module 5 according to the second embodiment. Here, the connector 54 to which terminals of the flexible wiring board 65 for signal transmission can be connected is arranged substantially in the center of the semiconductor element 51 in a plan view. The connector 53B to which terminals of the first flexible wiring board 61 can be connected and the connector 53A to which terminals of the second flexible wiring board 62 are connected are arranged in the vicinity of the outer periphery of the semiconductor element 51 in a plan view with a distance therebetween.

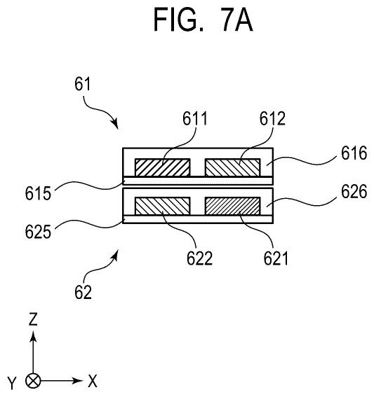

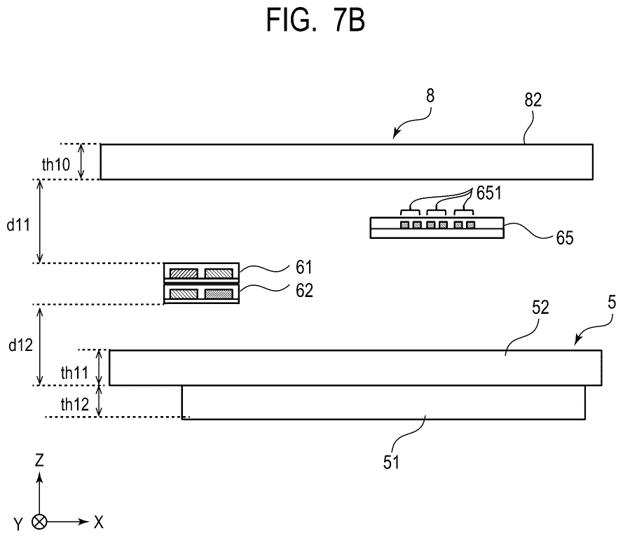

FIG. 7A is a sectional view along line A-A′ of the first flexible wiring board 61 and the second flexible wiring board 62 for power supply, illustrated in FIG. 6A. As illustrated in FIG. 7A, the first flexible wiring board 61 includes a power wiring 611, a power wiring 612, a base material 615, and a coverlay 616. The second flexible wiring board 62 includes a power wiring 621, a power wiring 622, a base material 625, and a coverlay 626. The base materials 615 and 625 are formed of polyimide. The base materials 615 and 625 are provided with copper wiring. The coverlays 616 and 626 are insulating members covering the wiring. The power wirings 611 and 612 of the first flexible wiring board 61 transmit the first power. The power wirings 621 and 622 of the second flexible wiring board 62 transmit the second power. In the first flexible wiring board 61, the power wiring 611 is arranged side by side with the power wiring 612 in the X-direction in a plan view. In the second flexible wiring board 62, the power wiring 621 for supplying the second power is arranged side by side with the power wiring 622 in the X-direction in a plan view. The power wiring 611 of the first flexible wiring board 61 is arranged to face the power wiring 622 of the second flexible wiring board 62 side by side in the Z-direction. Similarly, the power wiring 621 of the second flexible wiring board 62 is arranged to face the power wiring 612 of the first flexible wiring board 61 side by side in the Z-direction.

FIG. 7B is a cross-sectional view along line B-B′ of the power receiving module 5, the flexible wiring unit 6, and the wiring board 82 illustrated in FIG. 6A. A thickness th10 of the wiring board 82 and a thickness th11 of the wiring board 52 are, for example, 0.8 mm. A thickness th12 of the semiconductor element 51 is, for example, 0.7 mm. A distance d11 between the wiring board 82 and the first flexible wiring board 61 is, for example, 10.9 mm. A distance d12 between the wiring board 52 and the second flexible wiring board 62 is, for example, 10.9 mm. As illustrated in FIG. 7B, the distance between the first flexible wiring board 61 and the semiconductor element 51 is longer than the distance between the second flexible wiring board 62 and the semiconductor element 51. In such an arrangement, the DC voltage value supplied by the first flexible wiring board 61 may be higher than the DC voltage value supplied by the second flexible wiring board 62. That is, among the first flexible wiring board 61 and the second flexible wiring board 62, the flexible wiring board having a larger power to be transmitted may be disposed away from the semiconductor element 51. Thus, magnetic field noise affecting the semiconductor element 51 can be reduced.

As described above, in the first flexible wiring board 61, the power wiring 611 is arranged side by side with the power wiring 612 in the X-direction. In the power wiring 612, current flows in a direction opposite to that of the power wiring 601. Similarly, in the second flexible wiring board 62, the power wiring 621 is arranged side by side with the power wiring 622 in the X-direction. In the power wiring 622, current flows in a direction opposite to that in the power wiring 621. This increases the effect of canceling the magnetic field. The power wiring 611 of the first flexible wiring board 61 is arranged side by side with the power wiring 622 of the second flexible wiring board 62 in the Z-direction to face the power wiring 622. The power wiring 621 of the second flexible wiring board 62 is arranged side by side with the power wiring 612 of the first flexible wiring board 61 in the Z-direction to face the power wiring 612. As described above, the magnetic field cancellation effect can be enhanced by arranging the two power wirings in which currents in opposite directions flow side by side in the lateral direction (X-direction) and the vertical direction (Z-direction). If the widths of the power wirings are substantially the same, the magnetic field cancellation effect can be enhanced. Since the two flexible wiring boards are fixed, the relative positions of the plurality of power wirings can be maintained. Thus, the magnetic field noise reduction effect can be stably exhibited.

### Third Embodiment

Hereinafter, electronic equipment according to a third embodiment will be described. In the second embodiment described above, each of the first flexible wiring board 61 and the second flexible wiring board 62 for power supply has two power wirings. On the other hand, the third embodiment differs from the second embodiment in the number of wirings per flexible wiring board and in the arrangement of those wirings.

In the third embodiment, the meanings of the terms of the first to fourth power wirings, the first power, and the second power are the same as those in the first and second embodiments, description of which is incorporated by reference. Among a third pair of two power wirings for transmitting the third power, one power wiring is a fifth power wiring, and the other power wiring is a sixth power wiring. Among a fourth pair of two power wirings for transmitting the fourth power, one power wiring is a seventh power wiring, and the other power wiring is an eighth power wiring. While the third power and the fourth power are being transmitted, both the potential difference between the fifth power wiring and the eighth power wiring, and between the sixth power wiring and the seventh power wiring, are greater than the potential difference between the sixth power wiring and the eighth power wiring. While the third power and the fourth power are being transmitted, the relationship between the potential V5 applied to the fifth power wiring, the potential V6 applied to the sixth power wiring, the potential V7 applied to the seventh power wiring, and the potential V8 applied to the eighth power wiring is |V5-V8|>|V6 V8| and |V6-V7|>|V6-V8|. The potential difference between the sixth power wiring and the eighth power wiring may or may not be zero (|V6-V8|>0). V5 may be greater than V8, V5 may be less than V8, V6 may be greater than V7, V6 may be less than V7, V6 may be greater than or equal to V7, and V6 may be less than or equal to V7. In the following embodiments, V5>V6 is satisfied, that is, the fifth power wiring is regarded as a high potential wiring, and the sixth power wiring is regarded as a low potential wiring. Further, V7>V8 is satisfied, that is, the seventh power wiring is regarded as a high potential wiring and the eighth power wiring is regarded as a low potential wiring. However, even when either V5<V6 or V7<V8 is satisfied, it is sufficient that |V5-V8|>|V6-V8| and |V6-V7|>|V6-V8| are satisfied. In the following embodiments, both V5 and V7 are described as positive power supply potentials, and both V6 and V8 are described as ground potentials. The respective power supply potentials may be substantially the same, and the respective ground potentials may be substantially the same.

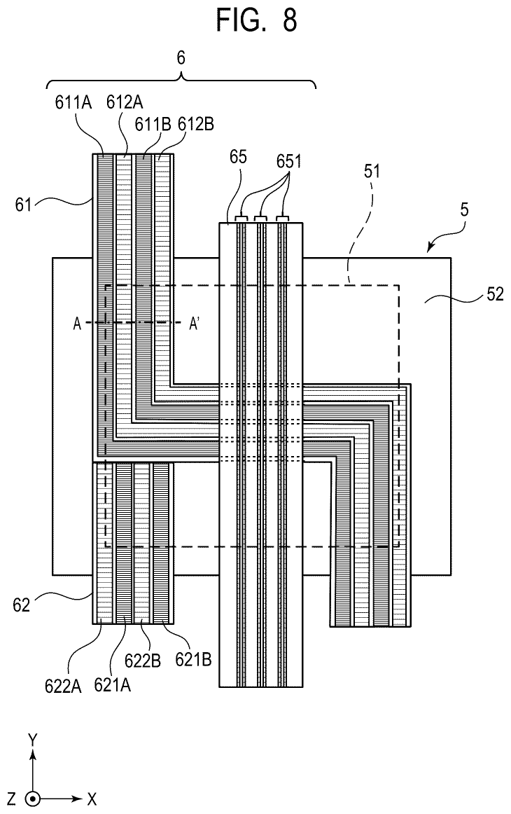

FIG. 8 is a plan view of a configuration of the power receiving module 5 and the flexible wiring unit 6 according to the third embodiment. FIG. 8 is a plan view of the wiring board 52 when viewed from the side of the wiring board 82. FIG. 8 illustrates the arrangement of the first flexible wiring board 61, the second flexible wiring board 62, the flexible wiring board 65, the semiconductor element 51, and the wiring board 52. The first flexible wiring board 61 and the second flexible wiring board 62 are single-sided flexible wiring boards with a conductor layer on only one surface.

The first flexible wiring board 61 of the present embodiment includes a power wiring 611A, a power wiring 612A, a power wiring 611B, and a power wiring 612B. The power wiring 611A is arranged side by side with the power wiring 612A in the X-direction. The power wiring 611A and the power wiring 612A transmit the first power. The power wiring 611A corresponds to a first power wiring to which the above-described power supply potential (potential V1) is applied. The power wiring 612A corresponds to the second power wiring to which the above-described ground potential (potential V2) is applied. The power wiring 611B is arranged side by side with the power wiring 612B in the X-direction. The power wiring 611B and the power wiring 612B transmit the third power from the power supply module 8 to the power receiving module 5. The power wiring 611B corresponds to the fifth power wiring to which the above-described power supply potential (potential V5) is applied. The power wiring 612B corresponds to the sixth power wiring to which the above-described ground potential (potential V6) is applied.

Similarly, the second flexible wiring board 62 includes a power wiring 622A, a power wiring 621A, a power wiring 622B, and a power wiring 621B. The power wiring 621A is arranged side by side with the power wiring 622A and the power wiring 622B in the X-direction. The power wiring 621A and the power wiring 622A transmit the second power. The power wiring 621A corresponds to the third power wiring to which the above-described power supply potential (potential V3) is applied. The power wiring 622A corresponds to the fourth power wiring to which the above-described ground potential (potential V4) is applied. The power wiring 621B is arranged side by side with the power wiring 622B in the X-direction. The power wiring 621B and the power wiring 622B transmit the fourth power from the power supply module 8 to the power receiving module 5. The power wiring 621B corresponds to the seventh power wiring to which the above-described power supply potential (potential V7) is applied. The power wiring 622B corresponds to the eighth power wiring to which the above-described ground potential (potential V8) is applied. In the third embodiment, the difference between the first power and the third power is less than the difference between the first power and the second power, and the difference between the second power and the fourth power is less than the difference between the third power and the fourth power. The values of the currents flowing through the power wiring 611A, the power wiring 621A, the power wiring 611B, and the power wiring 621B are greater than or equal to 0.5 [A] and less than or equal to 3.0 [A].

Arranging the wirings as described above confines the magnetic field noise generated in the high-potential wirings of the first flexible wiring board 61 and the second flexible wiring board 62, with the power wiring 622A and the power wiring 622B having the ground potential on both sides, and reduces the magnetic field noise reaching the semiconductor element 51.

The first flexible wiring board 61 and the second flexible wiring board 62 are arranged so that at least in part of them overlap in a plan view. That is, part or all of the first flexible wiring board 61 and the second flexible wiring board 62 overlap on a path until they are connected to the wiring board 82. As a result, the first flexible wiring board 61 and the second flexible wiring board 62 have an effect of canceling magnetic fields. By providing the first flexible wiring board 61 and the second flexible wiring board 62 for power supply, the power sources are separated. As a result, there is an effect of avoiding wiring migration.

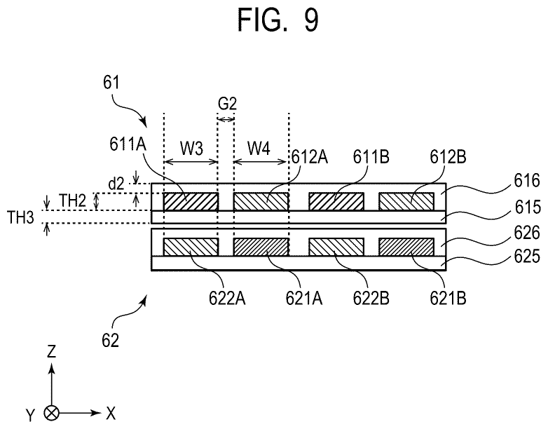

FIG. 9 is a cross-sectional view along A-A′ of the first flexible wiring board 61 and the second flexible wiring board 62 illustrated in FIG. 8. As illustrated in FIG. 9, the first flexible wiring board 61 includes the power wiring 611A, the power wiring 612A, the power wiring 611B, the power wiring 612B, the base material 615, and the coverlay 616.

The power wiring 611A is arranged side by side with the power wiring 622A of the second flexible wiring board 62 in the Z-direction. The power wiring 611B is arranged side by side with the power wiring 622B of the second flexible wiring board 62 in the Z-direction.

Similarly, the second flexible wiring board 62 includes the power wiring 622A, the power wiring 621A, the power wiring 622B, the power wiring 621B, the base material 625, and the coverlay 626.

The power wiring 621A is arranged side by side with the power wiring 612A of the first flexible wiring board 61 in the Z-direction. The power wiring 621B is arranged side by side with the power wiring 612B of the first flexible wiring board 61 in the Z-direction. In a plan view, the power wirings 611A, 612A, 611B, and 612B in the first flexible wiring board 61 overlap the power wirings 622A, 621A, 622B, and 621B in the second flexible wiring board 62, respectively.

A width W3 of the power wiring 611A and a width W4 of the power wiring 612A of the first flexible wiring board 61 are, for example, 630 μm. The width may be greater than or equal to 250 μm and less than or equal to 700 μm. A thickness TH2 of the power wiring 611A, the power wiring 612A, the power wiring 611B, and the power wiring 612B is, for example, 18 μm. A thickness TH3 of the base material 615 is, for example, 25 μm. A distance d2 from the upper surface of the wiring to the upper surface of the first flexible wiring board 61 is, for example, 30 μm. A spacing G2 between the power wiring 611A and the power wiring 612A is, for example, 70 μm. The spacing G2 may be greater than or equal to 60 μm and less than or equal to 80 μm. The width of the wiring in the second flexible wiring board 62 may be substantially the same as the width of the wiring in the first flexible wiring board 61. The distance of the wiring in the second flexible wiring board 62 may be substantially the same as the distance of the wiring in the first flexible wiring board 61.

According to the present embodiment, the low-potential wiring is arranged side by side with each of two high-potential wirings in the same flexible wiring board. In this way, the current is distributed and supplied, and the magnetic field noise caused by the current flowing in the high-potential wiring is canceled by the current flowing in the direction opposite to the high-potential wiring in the low-potential wiring. As a result, the magnetic field noise reaching the semiconductor element 51 from the flexible wiring unit 6 is further reduced.

### Fourth Embodiment

Hereinafter, electronic equipment according to a fourth embodiment will be described. The fourth embodiment differs from the third embodiment in the arrangement of power wirings for transmitting the first to fourth powers within the first flexible wiring board 61 and the second flexible wiring board 62, respectively. In the fourth embodiment, the meanings of the terms of the first to eighth power wirings and the first to fourth powers are the same as those of the third embodiment, description of which is incorporated by reference.

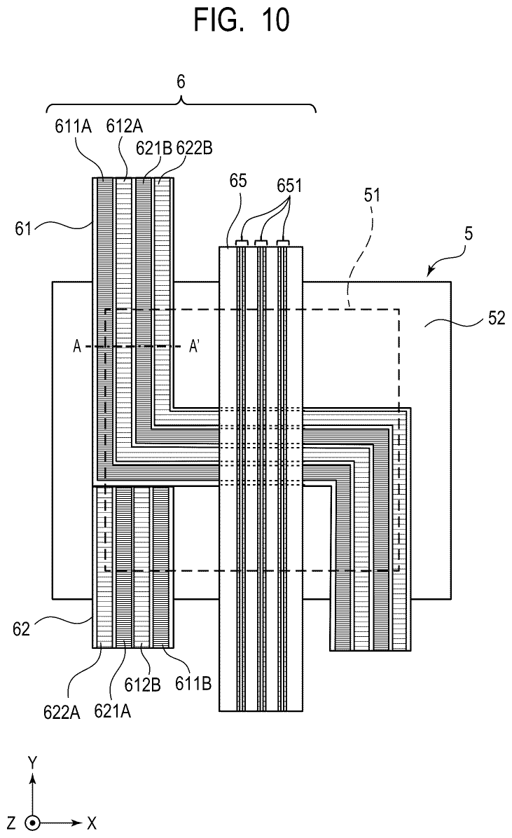

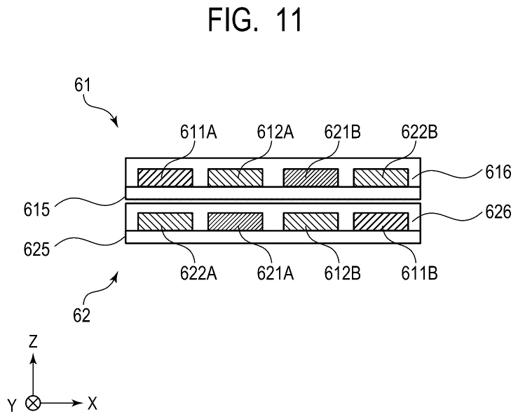

FIG. 10 is a plan view of a configuration of the power receiving module 5 and the flexible wiring unit 6 according to the fourth embodiment. FIG. 11 is a cross-sectional view taken along line A-A′ of the first flexible wiring board 61 and the second flexible wiring board 62 illustrated in FIG. 10.

In the first flexible wiring board 61 of the present embodiment, the first flexible wiring board 61 includes the power wirings 611A, 612A, 621B, 622B, the base material 615, and the coverlay 616. The power wiring 611A is arranged side by side with the power wiring 612A in the X-direction. The power wiring 611A and the power wiring 612A transmit the first power. The power wiring 611A corresponds to the first power wiring to which the above-described power supply potential (potential V1) is applied. The power wiring 612A corresponds to the second power wiring to which the above-described ground potential (potential V2) is applied. The power wiring 621B is arranged side by side with the power wiring 622B and the power wiring 612A in the X-direction. The power wiring 621B and the power wiring 622B transmit the third power from the power supply module 8 to the power receiving module 5. The power wiring 621B corresponds to the fifth power wiring to which the above-described power supply potential (potential V5) is applied. The power wiring 622B corresponds to the sixth power wiring to which the above-described ground potential (potential V6) is applied.

The second flexible wiring board 62 includes the power wiring 622A, the power wiring 621A, the power wiring 612B, the power wiring 611B, the base material 625, and the coverlay 626. The power wiring 621A of the second flexible wiring board 62 is arranged side by side with the power wiring 622A and the power wiring 612B in the X-direction. The power wiring 621A and the power wiring 622A transmit the second power. The power wiring 621A corresponds to the third power wiring to which the above-described power supply potential (potential V3) is applied. The power wiring 622A corresponds to the fourth power wiring to which the above-described ground potential (potential V4) is applied. The power wiring 611B is arranged side by side with the power wiring 612B in the X-direction. The power wiring 611B and the power wiring 612B transmit the fourth power from the power supply module 8 to the power receiving module 5. The power wiring 611B corresponds to the seventh power wiring to which the above-described power supply potential (potential V7) is applied. The power wiring 612B corresponds to the eighth power wiring to which the above-described ground potential (potential V8) is applied. In the fourth embodiment, the difference between the first power and the fourth power is less than the difference between the first power and the second power, and the difference between the second power and the third power is less than the difference between the third power and the fourth power.

As illustrated in FIG. 11, the power wiring 611A of the first flexible wiring board 61 is arranged side by side with the power wiring 622A of the second flexible wiring board 62 in the Z-direction. The power wiring 621B of the first flexible wiring board 61 is arranged side by side with the power wiring 612B of the second flexible wiring board 62 in the Z-direction.

The power wiring 621A of the second flexible wiring board 62 is arranged side by side with the power wiring 612A of the first flexible wiring board 61 in the Z-direction. The power wiring 611B of the second flexible wiring board 62 is arranged side by side with the power wiring 622B of the first flexible wiring board 61 in the Z-direction. In a plan view, the power wirings 611A, 612A, 621B, and 622B in the first flexible wiring board 61 overlap the power wirings 622A, 621A, 612B, and 611B in the second flexible wiring board 62, respectively.

The first flexible wiring board 61 and the second flexible wiring board 62 of the present embodiment each include two power systems for supplying different powers. Therefore, each of the first flexible wiring board 61 and the second flexible wiring board 62 can uniformly supply power sources having different voltage values to the semiconductor element 51 and the other circuit blocks of the wiring board 52, and a stable supply of power sources is provided. The power wiring 621B is arranged side by side between the power wirings 612A and 622B in the first flexible wiring board 61. Similarly, the power wiring 621A is arranged side by side between the power wiring 622A and the power wiring 612B in the second flexible wiring board 62. Since the high-potential wiring is arranged to be surrounded by two low-potential wirings in which a current in a direction opposite to that of the high-potential wiring flows, the effect of confining a magnetic field can be further demonstrated. The arrangement of the power wiring in the present embodiment is effective, for example, when the noise current flowing in the power wiring 621B and the power wiring 621A is greater than the noise current flowing in the power wiring 611A and the power wiring 611B.

### Fifth Embodiment

Hereinafter, electronic equipment according to a fifth embodiment will be described. The fifth embodiment differs from the third and fourth embodiments in the arrangement of the power wiring for transmitting the first to fourth powers within the first flexible wiring board 61 and the second flexible wiring board 62, respectively. In the fifth embodiment, the meanings of the terms of the first to eighth power wirings and the first to fourth powers are the same as those of the third embodiment, description of which is incorporated by reference.

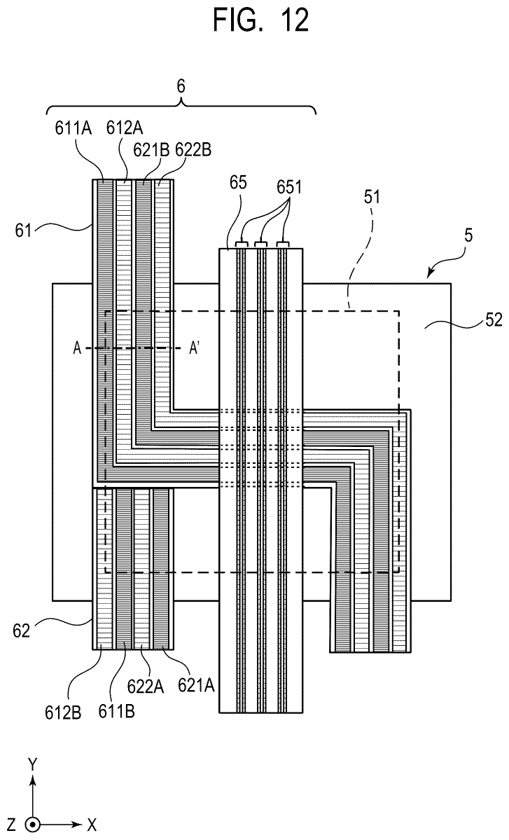

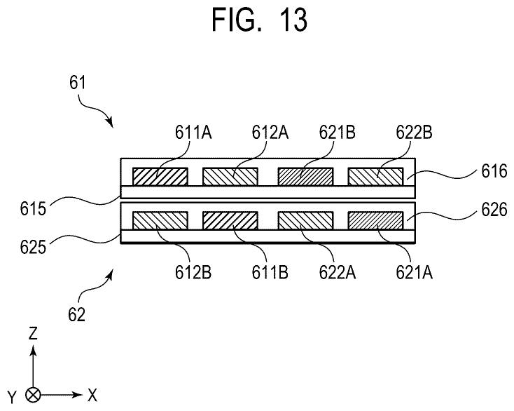

FIG. 12 is a plan view of a configuration of the power receiving module 5 and the flexible wiring unit 6 according to the fifth embodiment. FIG. 13 is a cross-sectional view along line A-A′ of the first flexible wiring board 61 and the second flexible wiring board 62 illustrated in FIG. 12.

The first flexible wiring board 61 of the present embodiment includes the power wiring 611A, the power wiring 612A, the power wiring 621B, the power wiring 622B, the base material 615, and the coverlay 616. The power wiring 611A is arranged side by side with the power wiring 612A in the X-direction. The power wiring 611A and the power wiring 612A transmit the first power. The power wiring 611A corresponds to the first power wiring to which the above-described power supply potential (potential V1) is applied. The power wiring 612A corresponds to the second power wiring to which the above-described ground potential (potential V2) is applied. The power wiring 621B is arranged side by side with the power wiring 612A and the power wiring 622B in the X-direction. The power wiring 621B and the power wiring 622B transmit the third power from the power supply module 8 to the power receiving module 5. The power wiring 621B corresponds to the fifth power wiring to which the above-described power supply potential (potential V5) is applied. The power wiring 622B corresponds to the sixth power wiring to which the above-described ground potential (potential V6) is applied.

The second flexible wiring board 62 includes the power wiring 612B, the power wiring 611B, the power wiring 622A, the power wiring 621A, the base material 625, and the coverlay 626. The power wiring 611B of the second flexible wiring board 62 is arranged side by side with the power wiring 622A and the power wiring 612B in the X-direction. The power wiring 611B and the power wiring 612B transmit the second power. The power wiring 611B corresponds to the third power wiring to which the above-described power supply potential (potential V3) is applied. The power wiring 612B corresponds to the fourth power wiring to which the above-described ground potential (potential V4) is applied. The power wiring 621A is arranged side by side with the power wiring 622A in the X-direction. The power wiring 621A and the power wiring 622A transmit the fourth power from the power supply module 8 to the power receiving module 5. The power wiring 621A corresponds to the seventh power wiring to which the above-described power supply potential (potential V7) is applied. The power wiring 622A corresponds to the eighth power wiring to which the ground potential (potential V8) described above is applied. In the present embodiment, the difference between the first power and the second power is less than the difference between the second power and the fourth power, and the difference between the third power and the fourth power is less than the difference between the first power and the third power.

As illustrated in FIG. 13, the power wiring 611A of the first flexible wiring board 61 is arranged side by side with the power wiring 612B of the second flexible wiring board 62 in the Z-direction. The power wiring 621B of the first flexible wiring board 61 is arranged side by side with the power wiring 622A of the second flexible wiring board 62 in the Z-direction.

The power wiring 621A of the second flexible wiring board 62 is arranged side by side with the power wiring 622B of the first flexible wiring board 61 in the Z-direction. The power wiring 611B of the second flexible wiring board 62 is arranged side by side with the power wiring 612A of the first flexible wiring board 61 in the Z-direction. In a plan view, the power wiring 611A, the power wiring 612A, the power wiring 621B, and the power wiring 622B in the first flexible wiring board 61 overlap the power wiring 612B, the power wiring 611B, the power wiring 622A, and the power wiring 621A in the second flexible wiring board 62, respectively.

The first flexible wiring board 61 and the second flexible wiring board 62 of the present embodiment each include two power systems for supplying different powers. Therefore, each of the first flexible wiring board 61 and the second flexible wiring board 62 can uniformly supply power sources having different voltage values to the semiconductor element 51 and the other circuit blocks of the wiring board 52, and a stable supply of power sources is provided. In addition, the power wirings 611A and 612A for supplying the first power, and power wirings 611B and 612B for supplying the second power are arranged in the left region with respect to the center position of the stacked flexible wiring boards. In addition, the power wirings 621B and 622B for supplying the third power, and the power wirings 621A and 622A for supplying the fourth power are arranged in the right region. The difference between the first power and the second power is less than the difference between the second power and the fourth power, and the difference between the third power and the fourth power is less than the difference between the first power and the third power. By grouping and arranging power wirings having a small difference in supply power, the magnetic field cancellation effect is enhanced in two directions of the X-direction and the Z-direction, and the magnetic field noise reduction effect can be further demonstrated.

For example, the power wirings 611A and 611B can be power wirings for power supply to a digital circuit, such as an image processing circuit. The power wirings 621B and 621A can be power wirings for power supply to an analog circuit, such as a pixel power supply circuit. The power wirings 611A and 611B can be configured as analog circuits, and the power wirings 621B and 621A can be configured as wiring corresponding to a digital circuit. By arranging power wirings of the same system close to each other in the X and Z-directions, the cancellation effect can be enhanced even if a current phase difference occurs.

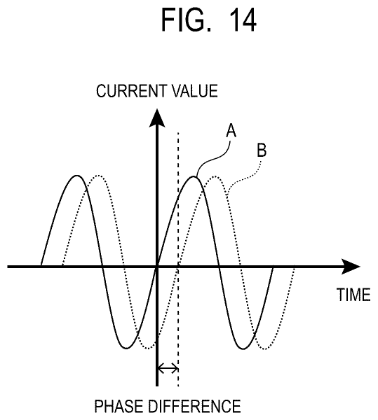

FIG. 14 is a graph of the phase difference of currents flowing through power wiring. The horizontal axis indicates time, and the vertical axis indicates a current value. As illustrated in FIG. 14, waveforms A and B indicate changes in the phases of currents flowing through two kinds of power wiring, respectively. Although the phases of currents flowing through the respective power wirings differ for each voltage value, the magnetic field can be effectively canceled by arranging the respective power wirings in alignment in the flexible wiring board.

### Sixth Embodiment

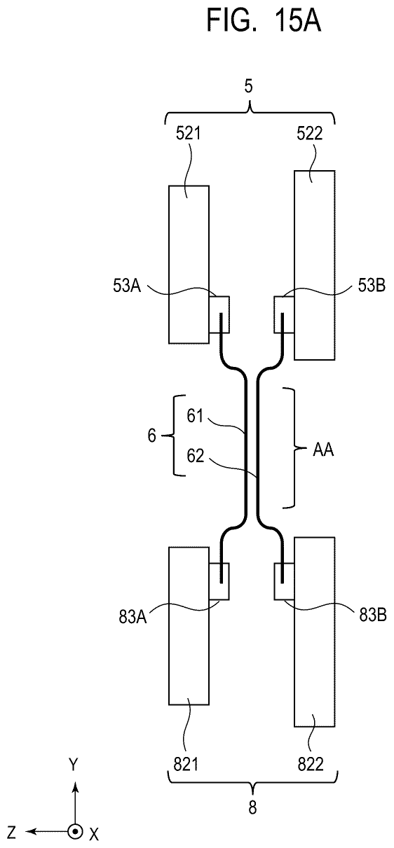

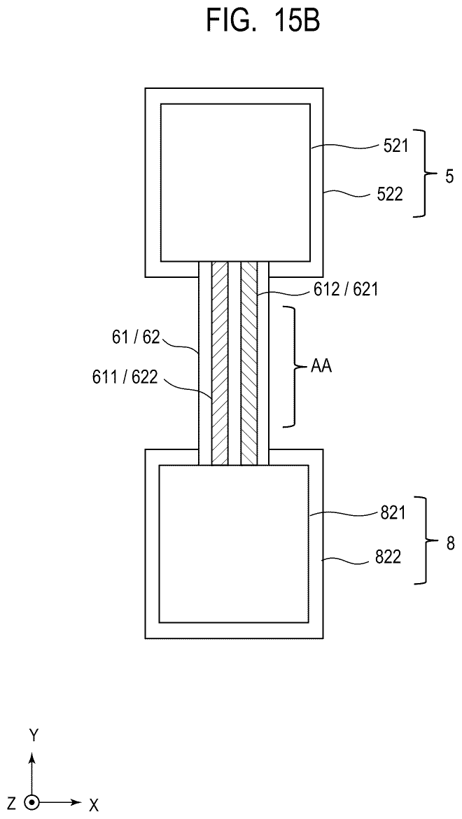

Hereinafter, electronic equipment according to a sixth embodiment will be described. FIG. 15A is a side view of a main portion of the electronic equipment. FIG. 15B is a plan view of a main portion of the electronic equipment. In the sixth embodiment, the power receiving module 5 includes a plurality of wiring boards 521 and 522, and the power supply module 8 includes a plurality of wiring boards 821 and 822. The respective configurations of the wiring boards 521 and 522 may be the same as those of the wiring boards 52 in other embodiments. The connector 53A and a semiconductor element are arranged on the wiring board 521, and the connector 53B and a power supply are arranged on the wiring board 522. The wiring boards 521 and 522 overlap in the Z-direction. The respective configurations of the wiring boards 521 and 522 may be the same as those of the wiring boards 82 in other embodiments. The connector 83A and a power supply are arranged on the wiring board 821, and the connector 83B and a power supply are arranged on the wiring board 822. The wiring board 821 and the wiring board 822 overlap in the Z-direction. The flexible wiring unit 6 includes flexible wiring boards 61 and 62. The flexible wiring board 61 connects the wiring board 821 and the wiring board 521, and the flexible wiring board 62 connects the wiring board 822 and the wiring board 522. The flexible wiring board 61 is provided with power wirings 611 and 612 described in another embodiment, and the flexible wiring board 62 is provided with power wiring 621 and power wiring 622 described in another embodiment.

In an AA region illustrated in FIGS. 15A and 15B, the flexible wiring board 61 and the flexible wiring board 62 are arranged close to each other. In the AA region, the flexible wiring board 61 may be adhered to the flexible wiring board 62 by an adhesive or may be closely adhered to the flexible wiring board 62 by a fixing member, such as a clip. The structure illustrated in FIGS. 15A and 15B may be modified, and for example, the flexible wiring unit 6 may be curved so that the wiring boards 521, 522, 821, and 822 overlap each other in the Z-direction.

In the AA region illustrated in FIGS. 15A and 15B, the wiring structure is similar to that illustrated in FIG. 7A. The power wiring 611 is arranged side by side with the power wiring 612 in the X-direction and arranged side by side with the power wiring 622 in the Z-direction. The power wiring 621 is arranged side by side with the power wiring 622 in the X-direction and arranged side by side with the power wiring 612 in the Z-direction. By arranging the power wiring in this manner, to reduce magnetic field noise.

### EXAMPLES

Regarding Examples 1-5 and Comparative Example 1, Examples 1-5 relate to the first to fifth embodiments described above. In Examples 1-5 and Comparative Example 1, an imaging surface was assumed as a circuit damaged by magnetic field noise, and a magnetic field simulation was performed for magnetic flux density reaching the imaging surface.

The simulation was performed using CST Studio Suite (manufactured by Dassault Systems, Inc.) under the following conditions. The width of each power wiring in Example 1 was 630 [μm], and the wiring pitch was 70 [μm]. The width of each power wiring in Examples 2-5 was 280 [μm], and the wiring pitch was 70 [μm]. The distance from the power wiring included in the first conductor layer or the first flexible wiring board to the power wiring included in the second conductor layer or the second flexible wiring board, that is, the distance between conductors, was 100 [μm]. The lengths of the flexible wiring boards in the longitudinal direction were all 40 [mm].

In the flexible wiring unit 6, the voltage for the analog circuit 57 was 3.5 [V], and the voltage for the digital circuit 58 was 1.25 [V]. The direct current (pulse current) flowing in each power wiring was 0.1 [A] for the power wiring corresponding to the Comparative Example 1 and the Examples 1 and 2, and 0.05 [A] was set for the power wiring corresponding to the Examples 3 to 5, and the frequency was 73 [kHz].

The phase difference between the current corresponding to the power wiring to which the potential of 3.5 [V] was applied and the current corresponding to the power wiring to which the potential of 1.25 [V] was applied was 30 [°]. The distance to the imaging surface to be the damaged circuit was 10.9 [mm], the imaging surface size was 39.2 [mm]×26.8 [mm], and the comparison was conducted with the maximum magnetic flux density [nT] in the surface as the arrival magnetic field.

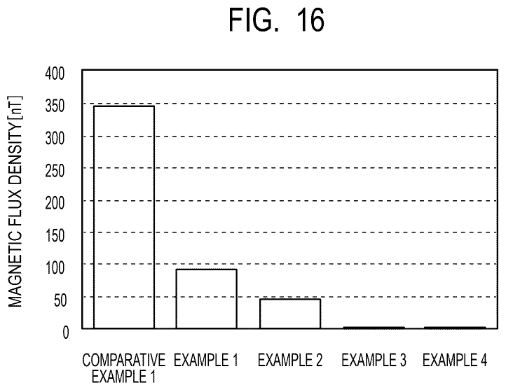

FIG. 16 is a graph illustrating the magnetic field simulation results. Example 1 illustrates the magnetic field simulation results corresponding to the first and second embodiments. Comparative Example illustrates the magnetic field simulation results in the case where the high potential wiring and the low potential wiring are arranged to face each other in the stacking direction of the first flexible wiring board 61 and the second flexible wiring board 62. Example 2 illustrates the magnetic field simulation results corresponding to the third embodiment, Example 3 illustrates the magnetic field simulation results corresponding to the fourth embodiment, and Example 4 illustrates the magnetic field simulation results corresponding to the fifth embodiment.

TABLE 1

| | MAXIMUM |
|---|---|
| | MAGNETIC |
| | FLUX |
| | DENSITY [nT] |
| COMPARATIVE | 346.9 |
| EXAMPLE 1 | |
| EXAMPLE 1 | 93.1 |
| EXAMPLE 2 | 46.5 |
| EXAMPLE 3 | 2.8 |
| EXAMPLE 4 | 1.6 |

The maximum magnetic flux density reaching the imaging plane in Example 1 was 93.1 [nT]. In Example 1, a reduction effect of 73.2 [%] was observed as compared with Comparative Example 1, in which power wirings with currents flowing in the same direction in the vertical direction (Z-direction) were arranged to face each other. According to the results of Example 1 and Comparative Example 1, a current flowing in a direction opposite to a certain power wire in another power wire arranged in the Z-direction (vertical direction) was found to greatly affect the cancellation of magnetic field noise.

The maximum magnetic flux density in Example 2 was 46.5 [nT]. In Example 2, different from Example 1, each flexible wiring board is provided with two power wirings through which current flows in the same direction. In Example 2, the magnetic field was reduced by 50.1% as compared with Example 1. Since each flexible wiring board has a plurality of power wirings through which current flows in the same direction, the radiation magnetic field is reduced.

The maximum magnetic flux density in Example 3 was 2.8 [nT]. In Example 3, the magnetic field cancellation effect was enhanced more than in Example 2 by arranging power sources with different current phase differences in each flexible wiring board and increasing the coupling in the oblique direction with the low-potential wirings arranged vertically and horizontally with respect to the high-potential wirings. According to Example 3, the maximum magnetic flux density was reduced to 94.0% of that in Example 2, even when the current phase difference occurred.

The maximum magnetic flux density in Example 4 was 1.6 [nT]. Example 4 confirmed a reduction effect of 42.9% more than was exhibited in Example 3 by increasing the coupling in the vertical and horizontal directions.

### Modified Embodiments

The present disclosure is not limited to the above-described embodiments, and modifications may be made within the technical concept of the present disclosure. The effects described in the embodiments list the effects resulting from the present disclosure, and the effects according to the present disclosure are not limited to those described in the embodiments.

In the above-described embodiments, the case where the electronic equipment is an imaging apparatus (digital camera) has been described, but the present disclosure is not limited to this case. The present disclosure is applicable as long as the electronic equipment includes a flexible wiring unit and mounts a power supply module and a power receiving module. For example, the electronic equipment may be a mobile communication apparatus. For example, the electronic equipment may be an information apparatus, such as a smartphone, or a communication apparatus, such as a modem or a router. Alternatively, the electronic equipment may be office equipment such as printers and copiers, medical equipment such as radiography equipment, magnetic imaging equipment, ultrasonic imaging equipment, and endoscopes, industrial equipment such as robots and semiconductor manufacturing equipment, and transportation equipment such as vehicles, airplanes, and ships. In a limited space in the casing of the electronic equipment, the configuration of the present disclosure can be used to reduce the size and density of the electronic equipment while suppressing noise. In the electronic equipment having a plurality of electronic modules, the configuration of the present disclosure can be used to reduce the size and density of the electronic equipment while suppressing noise. For example, the present disclosure is suitable for mobile terminals such as cellular phones, smartphones, tablet terminals, and notebook computers.

According to the present disclosure, electronic equipment is provided capable of reducing magnetic field noise.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-006919, filed Jan. 17, 2025, which is hereby incorporated by reference herein in its entirety.

What is claimed is:

1. Electronic equipment comprising:
a first module configured to supply a first power and a second power;
a flexible wiring unit that includes a first power wiring and a second power wiring for transmitting the first power, and a third power wiring and a fourth power wiring for transmitting the second power; and
a second module configured to receive the first power and the second power via the flexible wiring unit,
wherein, while the first power and the second power are being transmitted, each of a first potential difference between the first power wiring and the fourth power wiring, and a second potential difference between the second power wiring and the third power wiring, is greater than a third potential difference between the second power wiring and the fourth power wiring,
wherein the first power wiring is arranged alongside with the second power wiring in a first direction and is arranged alongside with the fourth power wiring in a second direction orthogonal to the first direction, and
wherein the third power wiring is arranged alongside with the fourth power wiring in the first direction and is arranged alongside with the second power wiring in the second direction.

2. The electronic equipment according to claim 1,
wherein a spacing between the first power wiring and the second power wiring in the first direction is smaller than a width of each of the first power wiring and the second power wiring in the first direction,
wherein a spacing between the third power wiring and the fourth power wiring in the first direction is smaller than a width of each of the third power wiring and the fourth power wiring in the first direction,
wherein a spacing between the first power wiring and the fourth power wiring in the second direction is smaller than a width of each of the first power wiring and the fourth power wiring in the first direction, and
wherein a spacing between the second power wiring and the third power wiring in the second direction is smaller than a width of each of the second power wiring and the third power wiring in the first direction.

3. The electronic equipment according to claim 1,
wherein, while the first power and the second power are being transmitted, a potential of the first power wiring is greater than a potential of the third power wiring.

4. The electronic equipment according to claim 1,
wherein the flexible wiring unit includes a first conductor layer and a second conductor layer,
wherein the first power wiring and the second power wiring are arranged in the first conductor layer, and
wherein the third power wiring and the fourth power wiring are arranged in the second conductor layer.

5. The electronic equipment according to claim 1,
wherein the flexible wiring unit includes a first flexible wiring board and a second flexible wiring board that are overlapped and arranged in the second direction,
wherein the first power wiring and the second power wiring are arranged in the first flexible wiring board,
wherein the third power wiring and the fourth power wiring are arranged in the second flexible wiring board.

6. The electronic equipment according to claim 1, further comprising:
a casing configured to store the first module, the flexible wiring unit, and the second module; and
a fixing member configured to fix the first flexible wiring board and the second flexible wiring board to the casing.

7. The electronic equipment according to claim 1,
wherein the flexible wiring unit includes a fifth flexible power wiring and a sixth power wiring configured to transmit a third power,
wherein the flexible wiring unit includes a seventh power wiring and an eighth power wiring configured to transmit a fourth power,
wherein the fifth power wiring is arranged alongside with the second power wiring and the sixth power wiring in the first direction and is arranged alongside with the eighth power wiring in the second direction,
wherein the seventh power wiring is arranged alongside with the eighth power wiring and the sixth power wiring in the first direction, and is arranged alongside with the sixth power wiring in the second direction, and
wherein at least one of followings is satisfied:
a difference between the first power and the third power is less than a difference between the first power and the second power, and a difference between the second power and the fourth power is less than a difference between the third power and the fourth power;
a difference between the first power and the fourth power is less than a difference between the first power and the second power, and a difference between the second power and the third power is less than a difference between the third power and the fourth power; and/or
a difference between the first power and the second power is less than a difference between the second power and the fourth power, and a difference between the third power and the fourth power is less than a difference between the first power and the third power.

8. The electronic equipment according to claim 1,
wherein a difference between the width of the first power wiring and the width of the second power wiring is less than a spacing between the first power wiring and the second power wiring in the first direction, and a difference between the width of the third power wiring and the width of the fourth power wiring is less than a spacing between the third power wiring and the fourth power wiring in the first direction.

9. The electronic equipment according to claim 1,
wherein the second module includes a semiconductor element to which the first power and the second power are supplied, and the flexible wiring unit overlaps the semiconductor element in the second direction.

10. The electronic equipment according to claim 9,
wherein the first power is greater than the second power, and a distance between the first power wiring and the semiconductor element is longer than a distance between the third power wiring and the semiconductor element.

11. The electronic equipment according to claim 5,
wherein the flexible wiring unit includes a third flexible wiring board configured to transmit signals,
wherein the first flexible wiring board is linearly formed,
wherein, in a plan view, the second flexible wiring board includes:
a first substrate portion which overlaps the first flexible wiring board and is connected to the second module;
a second substrate portion which does not overlap the first flexible wiring board and is connected to the first module; and
a third substrate portion between the first substrate portion and the second substrate portion,
wherein the third flexible wiring board intersects with the third substrate portion in a plan view.

12. The electronic equipment according to claim 5,
wherein the first power wiring is spaced apart from the fourth power wiring in the second direction, and
wherein a spacing between the second power wiring and the fourth power wiring is less than or equal to 500 μm.

13. The electronic equipment according to claim 1,
wherein the second module includes analog and digital circuits,
wherein the first power wiring is connected to the analog circuit, and
wherein the third power wiring is connected to the digital circuit.

14. The electronic equipment according to claim 7,
wherein the second module includes analog and digital circuits,
wherein the first power wiring and the third power wiring are connected to the analog circuit, and
wherein the fifth power wiring and the seventh power wiring are connected to the digital circuit.

15. The electronic equipment according to claim 1,
wherein at least one terminal of the flexible wiring unit is connected to connectors provided in the second module.

16. The electronic equipment according to claim 1,
wherein at least one terminal of the flexible wiring unit is soldered to a circuit board of the second module.

17. The electronic equipment according to claim 1,
wherein an electric current flowing through the first power wiring and the third power wiring are greater than or equal to 0.5 [A] and less than or equal to 3.0 [A].

18. The electronic equipment according to claim 1,
wherein, while the first power and the second power are being transmitted, a potential of the first power wiring is greater than a potential of the second power wiring, and a potential of the third power wiring is greater than a potential of the fourth power wiring.

19. The electronic equipment according to claim 1,
wherein the second module is configured to perform imaging.

20. The electronic equipment according to claim 1, further comprising:
a casing configured to store the first module, the flexible wiring unit, and the second module; and
a mechanism configured to move the second module relative to the first module in the casing.
